(19) United States
(12) Patent Application Publication
(10) Pub. No.: US 2024/0387420 A1
(43) Pub. Date: Nov. 21, 2024

(54) SEMICONDUCTOR PACKAGE IN A STACK FORM

(71) Applicant: SAMSUNG ELECTRONICS CO., LTD., Suwon-si (KR)

(72) Inventors: Soyeon Kwon, Suwon-si (KR); Jihun Jung, Suwon-si (KR); Yeongkwon Ko, Suwon-si (KR)

(21) Appl. No.: 18/438,335

(22) Filed: Feb. 9, 2024

(30) Foreign Application Priority Data
May 17, 2023 (KR) 10-2023-0064014
Aug. 7, 2023 (KR) 10-2023-0102915

(51) Int. Cl. H01L 23/00; H01L 25/065

(52) U.S. Cl. CPC H01L 24/05; H01L 24/06; H01L 24/16; H01L 24/17; H01L 25/0657; H01L 2224/0401; H01L 2224/05553; H01L 2224/06177; H01L 2224/16145; H01L 2224/17177

(57) ABSTRACT

The present disclosure relates to a semiconductor package including: a first semiconductor chip, a second semiconductor chip disposed on the first semiconductor chip; and at least one bump structure disposed between the first semiconductor chip and the second semiconductor chip, wherein the bump structure includes a first bump pad and a second bump pad with different planar areas.

### CROSS-REFERENCE TO RELATED APPLICATION

This application claims priority under 35 U.S.C. § 119 to Korean Patent Application No. 10-2023-0064014, filed in the Korean Intellectual Property Office on May 17, 2023, and Korean Patent Application No. 10-2023-0102915, filed in the Korean Intellectual Property Office on Aug. 7, 2023, the entire contents of which are incorporated by reference herein in their entirety.

### TECHNICAL FIELD

The technical spirit of the present disclosure relates to a semiconductor device, and more particularly, to a semiconductor package.

DISCUSSION OF RELATED ART

The demand for electronic products with smaller sizes, increased capacity, and enhanced performance has led to a need for greater integration and speed in semiconductor packages. In response, semiconductor packages that involve stacking multiple semiconductor chips including TSV structures have been developed.

For example, there is a growing interest in configuring package products in a stack form, such as high bandwidth memories (HBMs) employing high-speed serial links between semiconductor chips to greatly increase their memory bandwidths. This enables the provision of greater capacity within the same PCB area.

However, package products in such a stack form have a problem that the quality of bonding between chips is degraded by warpage.

### SUMMARY

The present disclosure attempts to provide a semiconductor package in a stack form with improved bonding quality by reducing warpage of the package product.

A semiconductor package according to an exemplary embodiment of the present disclosure including: a first semiconductor chip, a second semiconductor chip disposed on the first semiconductor chip; and at least one bump structure disposed between the first semiconductor chip and the second semiconductor chip, wherein the bump structure includes a first bump pad and a second bump pad with different planar areas.

A semiconductor package according to an exemplary embodiment of the present disclosure including: a first semiconductor chip; a second semiconductor chip disposed on the first semiconductor chip; and at least one bump structure that is disposed between the first semiconductor chip and the second semiconductor chip, electronically connecting the two, wherein the bump structure includes a first bump pad and a second bump pad, and their planar areas differ. Rear surfaces of the first semiconductor chip and the second semiconductor chip include center regions and edge regions that surrounds the center regions, and densities of the bump structures on the center regions and densities of the edge regions are different from each other.

A semiconductor package according to an exemplary embodiment of the present disclosure including: a package substrate; an interposer that is disposed on the package substrate; and a semiconductor stack structure that is disposed on the interposer and in which a plurality of semiconductor chips is stacked. The semiconductor stack structure includes at least one bump structure that is disposed between the plurality of semiconductor chips, wherein the bump structure includes a first bump pad and a second bump pad with different planar areas, and the planar area of the bump structure is in contact with either the first semiconductor chip or the second semiconductor chip. Either the first bump pad or the second bump pad includes an extension portion that extends horizontally in at least one direction, and the direction includes a first direction, a direction opposite to the first direction, a second direction intersecting the first direction in a horizontal direction; and a direction opposite to the second direction.

### BRIEF DESCRIPTION OF DRAWINGS

FIG. 1A is a cross-sectional view of a semiconductor package according to an exemplary embodiment of the present disclosure, and FIG. 1B is an enlarged view of region P in FIG. 1A.

FIG. 2A is an enlarged view of region A in FIG. 1B, and FIG. 2B shows a front view as seen from above the top in FIG. 2A.

FIGS. 3A, 3B, 3C, and 3D are various exemplary embodiments of region A in FIG. 1B.

FIGS. 4A, 4B, 4C, 4D, 4E, 4F, 4G, 4H, 4I, and 4J are cross-sectional views of

region BB′ in FIG. 1B.

FIG. 5 is the rear surface of a first semiconductor chip or a second semiconductor chip.

FIGS. 6A and 6B are arrangements of bump structures on the rear surfaces of semiconductor chips.

FIGS. 7A and 7C are various arrangements of bump structures according to an exemplary embodiment of the present disclosure.

FIGS. 8A and 8D are various arrangements of bump structures according to an exemplary embodiment of the present disclosure.

FIG. 9 is a semiconductor package according to an exemplary embodiment of the present disclosure.

FIGS. 10A, 10B, 10C, 10D, 10E, and 10F are methods of manufacturing a semiconductor package according to an exemplary embodiment of the present disclosure.

### DETAILED DESCRIPTION

In the following detailed description, only certain exemplary embodiments of the present disclosure have been shown and described, simply by way of illustration. The present disclosure can be variously implemented and is not necessarily limited to the following exemplary embodiments.

The drawings and description are to be regarded as illustrative in nature and not necessarily restrictive. Like reference numerals designate like elements throughout the specification.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane” or “in a plan view”, it means when a target part is viewed from above, and when it is referred to as “on a cross-section”, it means when the cross-section obtained by cutting a target part vertically is viewed from the side.

Hereinafter, exemplary embodiments of the present disclosure will be described in detail such that they can be easily carried out by those skilled in the art. However, the present disclosure may be modified in various ways and are not necessarily limited to the exemplary embodiments to be described herein.

Referring to the detailed description, D1 may indicate a first direction, D2 may indicate a second direction that intersects the first direction D1, and D3 may indicate a third direction that intersects each of the first direction D1 and the second direction D2. The D1 or D3 direction may be called a horizontal direction. The second direction D2 may be called a vertical direction or an upward direction. A negative sign (−) may indicate a direction opposite to that of the first, second, and third directions.

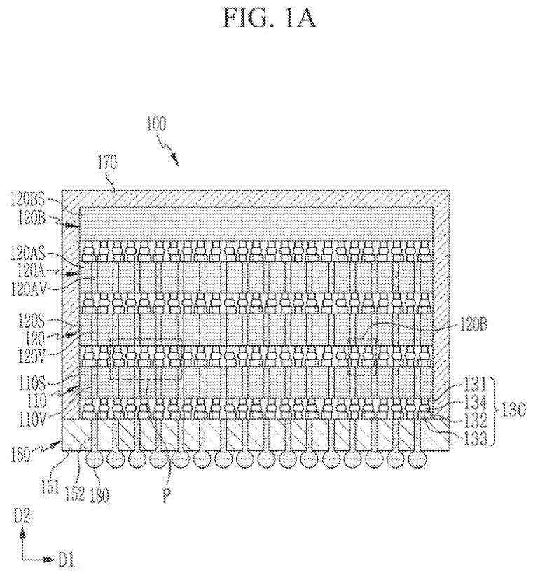

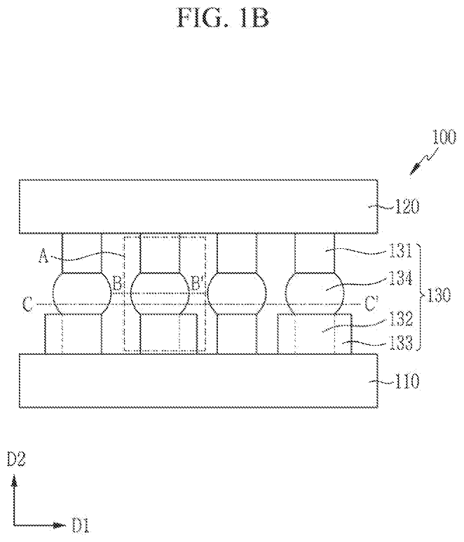

FIG. 1A is a cross-sectional view of a semiconductor package 100 according to an exemplary embodiment of the present disclosure, and FIG. 1B is an enlarged view of region P in FIG. 1A.

Referring to FIG. 1A, the semiconductor package 100 may include a plurality of semiconductor chips 110, 120, 120A, and 120B, a base chip 150, bonding layers, and a sealing material. For example, the semiconductor package 100 may be a structure in which the plurality of semiconductor chips 110, 120, 120A, and 120B is stacked in a second direction D2, like a high bandwidth memory (HBM). In FIG. 1A, it is shown that the plurality of semiconductor chips 110, 120, 120A, and 120B is stacked in four layers; however, the exemplary embodiment is not necessarily limited thereto. For example, eight or more semiconductor chips may be arranged.

The plurality of semiconductor chips 110, 120, 120A, and 120B may be stacked. For example, the plurality of semiconductor chips 110, 120, 120A, and 120B includes a plurality of semiconductor chips such as the first semiconductor chip 110 and a second semiconductor chip 120. The second semiconductor chips 120 are disposed on the first semiconductor chips 110. Hereinafter, the plurality of semiconductor chips 110, 120, 120A, and 120B will be described in reference to the first semiconductor chip 110. The second to fourth semiconductor chips 120, 120A, and 120B may draw upon the description provided for the first semiconductor chip 110.

The first semiconductor chip 110 may include a first substrate member 110S and first through silicon vias (TSVs) 110V. The first substrate member 110S may include a first substrate and a first element layer. The first substrate may be a substrate including semiconductor elements. For example, the semiconductor elements may include an element such as silicon (Si) or germanium (Ge). For example, the first substrate may include, for example, a compound semiconductor such as silicon carbide (SiC), gallium arsenide (GaAs), indium arsenide (InAs), or indium phosphide (InP), but is not necessarily limited thereto.

The first substrate may have a silicon-on-insulator (SOI) structure. For example, the first substrate may include a buried oxide layer (BOX layer). The first substrate may include conductive regions such as wells doped with impurities or structures doped with impurities. The first substrate may include various element isolation structures such as shallow trench isolation (STI) structures.

The first element layer may include various types of elements depending on the type of chip. For example, the first element layer may include various active elements and/or passive elements, such as field effect transistors (FETs) like planar field effect transistors and FinFETs, memories like flash memories, dynamic random access memories (DRAMs), static random access memories (SRAMs), electrically erasable programmable read-only memories (EEPROMs), phase-change random access memories (PRAMs), magnetoresistive random access memories (MRAMs), ferroelectric random access memories (FeRAMs), and resistive random access memories (RRAMs), logic gates like AND, OR, and NOT gates, a system LSI (large-scale integration), CMOS imaging sensors (CISs), and a micro-electro-mechanical system (MEMS).

For example, the element layer may include volatile memory semiconductor chips such as DRAMs or SRAMs, or non-volatile memory elements such as PRAMs, MRAMs, FeRAMs, or RRAMs. For example, the first semiconductor chip 110 may be a high bandwidth memory (HBM) DRAM chip including DRAM elements in the first element layer.

The first TSVs 110V may electrically couple structures disposed on the upper part and lower part of the first substrate member 110S. The first TSVs 110V may extend from the upper surface of the first substrate member 110S to the lower surface of the first substrate member 110S and may vertically pass through the first substrate member 110S. For example, the first TSVs 110V may have a columnar shape. The columnar shape refers to a structure that is shaped like a column, which is a vertical cylindrical pillar. The first TSVs 110V may include various conductive materials such as copper (Cu), tungsten (W), nickel (Ni), ruthenium (Ru), or cobalt (Co).

The first TSVs 110V may be arranged at uniform or varying intervals in a line along a first direction D1 direction in FIG. 1A. However, the present arrangements are not necessarily limited thereto and the first TSVs 110V may be arranged in different ways. In an exemplary embodiment, the first TSVs 110V may include outer barrier

layers and inner buried conductive layers. The barrier layers may include Ti, TiN, Ta, TaN, Ru, Co, Mn, WN, Ni, and/or NiB. The buried conductive layers may include Cu alloys, W, W alloys, Ni, Ru, and/or Co. For example, the buried conductive layers may include a material such as Cu, CuSn, CuMg, CuNi, CuZn, CuPd, CuAu, CuRe, or CuW.

In an exemplary embodiment, via insulating layers may be disposed between the first substrate member 110S and the first TSVs 110V. The via insulating layers may include oxide films, nitride films, carbide films, a polymer, or a combination thereof.

In an exemplary embodiment, bump structures 130 may be disposed between the first semiconductor chip 110 and the second semiconductor chip 120. The bump structures 130 may electrically connect the first semiconductor chip 110 and the second semiconductor chip 120. For example, the bump structures 130 may electrically connect the first TSVs 110V of the first semiconductor chip 110 and second TSVs 120V of the second semiconductor chip 120 and prevent warpage of the first semiconductor chip 110 and the second semiconductor chip 120.

The bump structures 130 may include first bump pads 131, second bump pads 132, and solder bumps 134. The first bump pads 131 and the second bump pads 132 may be aligned with each other in the vertical direction. For example, the first bump pads 131 are disposed on the second bump pads 132. The solder bumps 134 are disposed between the first bump pads 131 and the second bump pads 132.

In an exemplary embodiment, the first bump pads 131 may be coupled to the second TSVs 120V of the second semiconductor chip 120 that is stacked on the first semiconductor chip 110. The second bump pads 132 may be coupled to the first TSVs 110V of the first semiconductor chip 110. Some of the first bump pads 131 and the second bump pads 132 may electrically connect the first TSVs 110V and the second TSVs 120V, thereby electrically connecting the semiconductor chips.

In an exemplary embodiment, the first bump pads 131 might not be coupled to the second TSVs 120V of the second semiconductor chip 120 that is stacked on the first semiconductor chip 110. For example, some of the first bump pads 131 and the second bump pads 132 might not connect with the first TSVs 110V and the second TSVs 120V to prevent warpage of the first semiconductor chip 110 and the second semiconductor chip 120.

The first bump pads 131 and the second bump pads 132 may be formed of conductive materials such as aluminum (Al), copper (Cu), nickel (Ni), tungsten (W), platinum (Pt), and/or gold (Au). The first bump pads 131 and the second bump pads 132 may include the above-mentioned conductive materials to electrically connect the first TSVs 110V of the first semiconductor chip 110 and the second TSVs 120V of the second semiconductor chip 120 and to increase the metal wetting force of the semiconductor chips in the process of bonding the semiconductor chips.

In an exemplary embodiment, the planar areas of the first bump pad 131 and the second bump pad 132 within each bump structure 130 may vary. The planar areas of the first bump pad 131 or the second bump pad 132 may be in contact with the first semiconductor chip 110 or the second semiconductor chip 120. For example, either the first bump pad 131 or the second bump pad 132 may include an extension portions 133, resulting in a larger planar area compared to bump pads 131 and 132 without extension portions. For example, the planar area of the first bump pad 131 may be either smaller or larger than that of the second bump pad 132.

The solder bump 134 may electrically connect the first bump pad 131 and the second bump pad 132. For example, the solder bump 134 may be disposed between the first bump pad 131 and the second bump pad 132, in various forms. The solder bump 134 may include tin (Sn), indium (In), bismuth (Bi), antimony (Sb), copper (Cu), silver (Ag), zinc (Zn), lead (Pb), and/or an alloy thereof. For example, the solder bump 134 may include a material such as Sn, Pb, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, or Sn—Bi—Zn.

In an exemplary embodiment, between the first and second bump pads 131 and 132 and the solder bump 134, diffusion barrier layers and/or bonding layers may be formed. The diffusion barrier layers may include nickel (Ni), cobalt (Co), copper (Cu), or a combination thereof. The bonding layers may include nickel (Ni), copper (Cu), palladium (Pd), cobalt (Co), platinum (Pt), gold (Au), or a combination thereof.

Referring to FIG. 1B, in an exemplary embodiment, the bump pad 131 and 132 with the larger area, whether it be the first bump pad 131 or the second bump pad 132, may include an extension portion 133. Extension portions 133 may be included in either the first bump pad 131 and/or the second bump pad 132 such that the first bump pad 131 and the second bump pad 132 have different areas.

Extension portions 133 may be disposed on at least one side of the first bump pad 131 or the second bump pad 132. The extension portions 133 may include the same or similar material as the first bump pad 131 and the second bump pad 132. Additionally, the extension portions 133 may be formed simultaneously when the first bump pad 131 or the second bump pad 132 is formed. The exemplary embodiment, however, is not necessarily limited thereto. For example, extension portions 133 may be formed after the first bump pad 131 or the second bump pad 132 is formed.

The extension portions 133 may come into contact with either the first bump pad 131 and/or the second bump pad 132 such that the areas of the first bump pad 131 and the second bump pad 132 are different from each other, allowing metal in contact with either the first semiconductor chip 110 or the second semiconductor chip 120 to have different densities. For example, either the first bump pads 131 or the second bump pads 132 including the extension portions 133 may have increased metal density at the points where the bump pads 131 and 132 make contact with the first semiconductor chip 110 or the second semiconductor chip 120. Increasing the density of metal abutting the first semiconductor chip 110 or the second semiconductor chip 120 may prevent warpage of the plurality of semiconductor chips 110, 120, 120A, and 120B and poor bonding between the semiconductor chips.

The base chip 150 may include a base substrate member 151 and base through silicon vias (TSVs) 152. The base substrate member 151 and the base TSVs 152 are at least similar to the first substrate member 110S and the first TSVs 110V of the first semiconductor chip 110 that have been described above within the present disclosure.

The bonding layers may be interposed between the plurality of semiconductor chips 110, 120, 120A, and 120B. Additionally, the bonding layers may be interposed between the base chip 150 and the first semiconductor chip 110, so as to at least partially surround the side surfaces of the bump structures 130. For example, the bonding layers may at least partially surround the outer side surfaces of the first bump pads 131 and the second bump pads 132. The bonding layers may protrude outward from the side surfaces of the plurality of semiconductor chips 110, 120, 120A, and 120B.

The bonding layers may be formed of non-conductive films (NCFs). The non-conductive films may serve as an adhesive to bond the plurality of semiconductor chips 110, 120, 120A, and 120B, or bond the first semiconductor chip 110 and the base chip 150.

The non-conductive films may be used as bonding layers when bonding the semiconductor chips in a thermal compression bonding (TCB) manner in a semiconductor chip stacking process. For example, in the thermal compression bonding manner, the non-conductive films may be melted to have fluidity.

The non-conductive films may include materials that help prevent the substrates from being warped by a difference in thermal expansion coefficient between the plurality of semiconductor chips 110, 120, 120A, and 120B or between the first semiconductor chip 110 and the base chip 150. For example, the non-conductive films may include an epoxy material.

The sealing material may at least partially surround the side surfaces of the plurality of semiconductor chips 110, 120, 120A, and 120B and the bonding layers. The sealing material may cover the upper surface of the fourth semiconductor chip 120B disposed at the top of the plurality of semiconductor chips 110, 120, 120A, and 120B, to a predetermined thickness.

In an exemplary embodiment, the sealing material might not be formed on the upper surface of the fourth semiconductor chip 120B. Accordingly, the upper surface of the fourth semiconductor chip 120B may be exposed to the outside. The sealing material may include a thermosetting resin such as an epoxy molding compound (EMC) but is not necessarily limited thereto.

In an exemplary embodiment, bumps 180 may be disposed below the base chip 150. The bumps 180 may be electrically connected to the base TSVs 152 through a wiring structure in the element layer of the base chip 150. The exemplary embodiment, however, is not necessarily limited thereto. For example, some embodiments may include every semiconductor package including at least one bump structure 130 as illustrated in FIG. 1B.

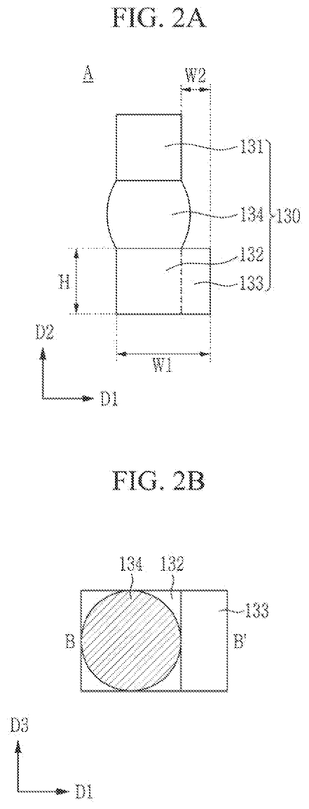

FIG. 2A is an enlarged view of region A in FIG. 1B, and FIG. 2B is a FIG. 2A in a plan view.

Referring to FIG. 2A and FIG. 2B, in an exemplary embodiment, the extension portions 133 may extend in various directions. For example, the extension portions 133 may extend in at least one direction parallel to the first direction D1, the opposite to the first direction −D1, the third direction D3, and the opposite to the third direction −D3. These extensions originate from either the first bump pad 131 and/or the second bump pad 132.

For example, of the first and second bump pads 131 and 132, the bump pad including the extension portions 133 and a larger planar area may have a structure extending in at least one direction of the first direction D1, the opposite to the first direction −D1, the third direction D3, and the opposite direction of the third direction −D3. For example, the extension portions 133 may be disposed on the first bump pad 131 facing the second bump pad 132 and may extend in one of the four horizontal directions from the central axes of the first bump pad 131. A similar configuration may apply to the second bump pad 132.

In an exemplary embodiment, a ratio of a width W1 of a bump pad including the extension portion 133 to a height H of a bump pad including the extension portion 133 may be equal to or larger than 7.5. In FIG. 2A, the height H of a bump pad refers to the length of the first bump pad which includes the extension portion 133, in the D2 direction (D2). In FIG. 2A, the width W1 of a bump pad including an extension portion 133 refers to the length of the first bump pad 131 which includes the extension portion 133, in the first direction D1.

The ratio of the width W1 of a bump pad including the extension portion 133 to the height H of a bump pad including the extension portion 133 may be equal to or larger than 8.0. When the above-mentioned ratio is less than 7.5, a high density of metal abutting a semiconductor chip might not be achieved. Thus, it may be ineffective in restraining the warpage of the semiconductor chip. When the above-mentioned ratio is set to be equal to or larger than 8.0, such that the densities of metal abutting semiconductor chips that are stacked are different from each other, it may be possible to prevent warpage of thin semiconductor chips during stacking or prevent semiconductor chips from being warped in a high-temperature bonding process.

In an exemplary embodiment, a length W2 of the extension portion 130 is in a direction parallel with a front surface of the first semiconductor chip 110 or the second semiconductor chip 120. The length W2 of the extension portion 130 is measured in the first direction D1. The length W2 of the extension portion 130 may be larger than 0 and equal to or smaller than 0.8 μm. For example, the length W2 may be larger than 0 and equal to or smaller than 0.5 μm.

When the length W2 surpasses the specified upper limit of 0.8 μm, the extension portion 130 may become overly lengthy, causing potential interference issues with other bump structures disposed apart from each other.

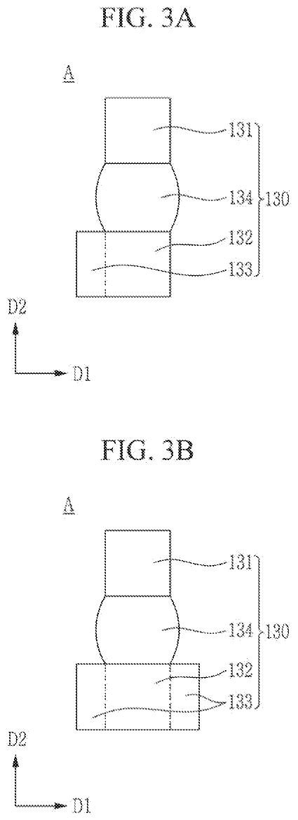

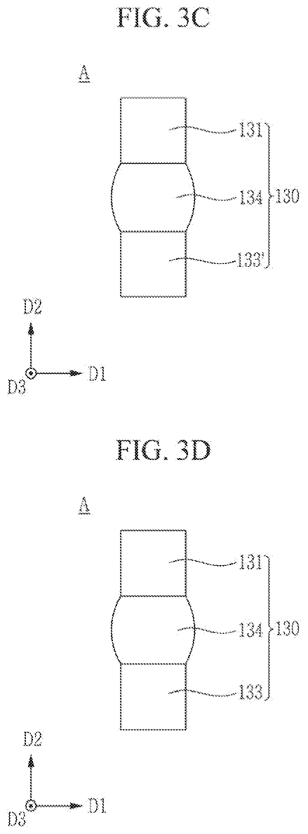

FIG. 3A to FIG. 3D are various exemplary embodiments of region A in FIG. 1B.

Referring to FIG. 3A and FIG. 3B, in an exemplary embodiment, the extension portions 133 may extend in either the first direction D1 and/or the opposite to the first direction −D1 from any one of a first bump pad 131 and a second bump pad 132. For example, when the extension portions 133 are disposed on at least one side surface of the second bump pad 132, they may extend in at least one direction of the first direction D1, or the opposite to the first direction −D1 from the second bump pad 132.

FIG. 3A shows that an extension portion 133 extends in the opposite to the first direction −D1, and FIG. 3B shows that extension portions 133 extends in both the first direction D1 and the opposite to the first direction −D1. The exemplary embodiment, however, is not necessarily limited thereto. For example, the extension portion 133 may extend only in the D1 direction (D1) or may be disposed on one side surface of the first bump pad 131, not the second bump pad 132.

Referring to FIG. 3C and FIG. 3D, in an exemplary embodiment, extension portions 133′ may extend in at either a third direction D3 and/or opposite to the third direction −D3 from any one of a first bump pad 131 and a second bump pad 132.

FIG. 3C shows the extension portion 133′ extending in the opposite to the third direction −D3, and FIG. 3D the extension portion 133′ extending in the third direction D3.

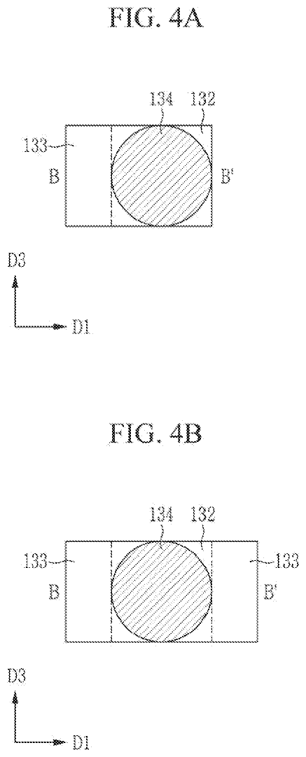

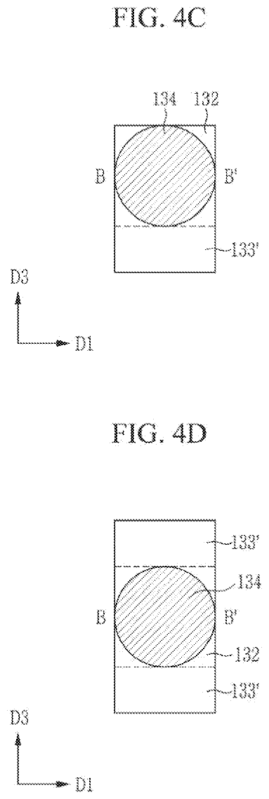

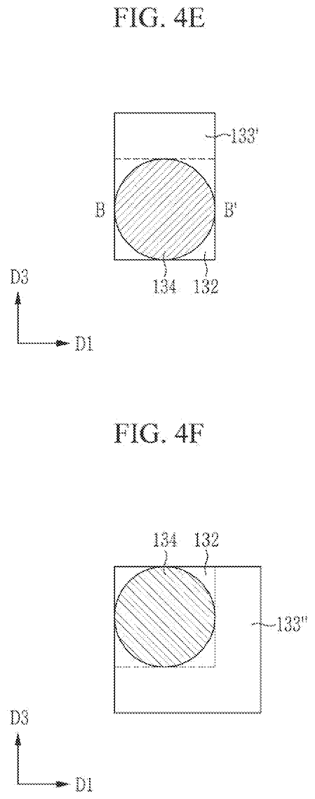

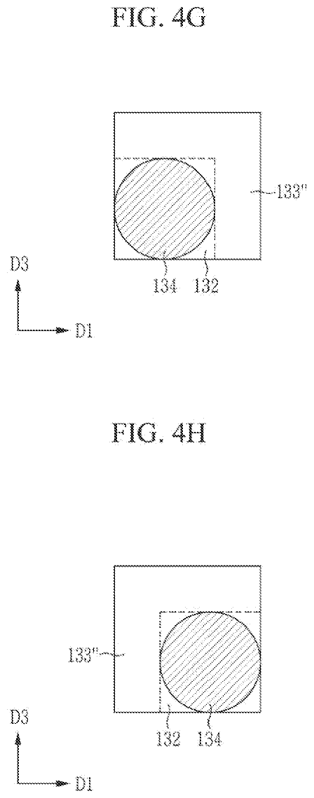

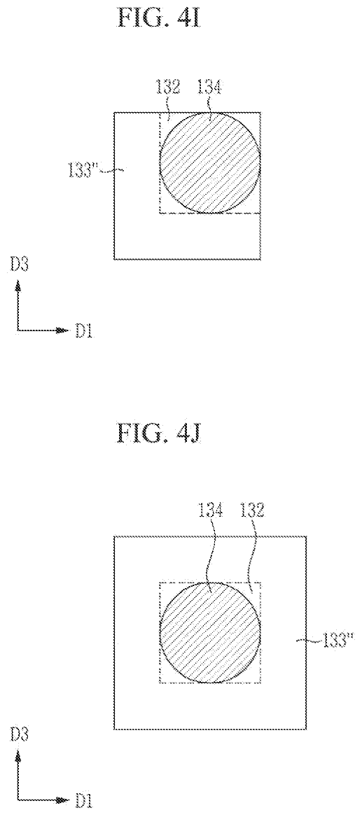

FIG. 4A to FIG. 4J are cross-sectional views of region BB′ in FIG. 1B.

Referring to FIG. 4A and FIG. 4B, extension portions 133 may extend in at least one direction of the first direction D1 and the opposite to the first direction −D1 from a second bump pad 132, like in FIG. 3A and FIG. 3B.

Referring to FIG. 4C to FIG. 4E, extension portions 133′ may extend in at least one direction of the third direction D3 and the opposite to the third direction −D3 from a second bump pad 132.

Referring to FIG. 4C and FIG. 4D, extension portions 133′ may extend in the third direction D3 or opposite to the third direction −D3 from a second bump pad 132, like in FIG. 3C. Referring to FIG. 4E, the extension portion 133′ may extend in the third direction D3, like in FIG. 3D.

Referring to FIG. 4F to FIG. 4I, an extension portion 133″ may extend in at least one direction of the first direction D1 and opposite to the first direction −D1 and in at least one direction of the third direction D3 and the opposite direction to the third direction −D3 from a second bump pad 132. For example, the extension portion 133″ may extend at least two directions from a second bump pad 132.

For example, in FIG. 4F, the extension portion 133″ may extend in the first direction D1 and opposite to the third direction −D3 from the second bump pad 132. In FIG. 4G, the extension portion 133″ may extend in the first direction D1 and the third direction D3.

In FIG. 4H, the extension portion 133″ may extend in the opposite to the first direction −D1 and the t third direction D3. In FIG. 4I, the extension portion 133″ may extend in the opposite to the first direction −D1 and the opposite to the third direction −D3.

Referring to FIG. 4J, an extension portion 133″ may extend in the first direction D1 which is horizontal, the opposite to the first direction −D1, the third direction D3, and the opposite to the third direction −D3 which intersects the first direction D1 from a second bump pad 132.

For example, an extension portion 133″ may extend in four directions from a second bump pad 132. For example, the extension portion 133″ may extend in the horizontal direction of the first direction D1, which is relative to the vertical second direction D2 of the second bump pad 132. Additionally, the extension portion 133″ may extend in opposite to the first direction −D1, the third direction D3, and opposite to the third direction −D3. The exemplary embodiment, however, is not necessarily limited thereto. For example, the extension portion 133″ may extend in three directions: the first direction D1, the opposite to the first direction −D1, the third direction D3, and the opposite to the third direction −D3.

In FIG. 4A to FIG. 4J, it is shown that the extension portions 133, 133′, or 133″ extend from the second bump pad 132. The exemplary embodiment, however, is not necessarily limited thereto. For example, the extension portions may be disposed on a first bump pad 131. For example, the extension portions 133, 133′, or 133″ may be disposed only on the first bump pad 131, only on the second bump pad 132, or on both the first bump pad 131 and the second bump pad 132, provided that the metal densities in contact with semiconductor chips 110 and 120 differ from each other. As described above, the extension portions 133, 133′, or 133″ control the metal densities of the bump pads 131 and 132, thereby controlling warpage of the semiconductor chips and the semiconductor package.

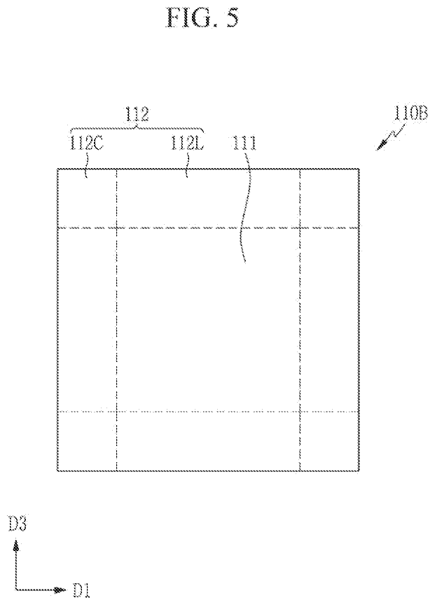

FIG. 5 shows a rear surface 110B of the first semiconductor chip or the second semiconductor chip.

Referring to FIG. 5, in an exemplary embodiment, the rear surface 110B of a semiconductor chip may include a center region 111 and an edge region 112 at least partially surrounding the center region 111. The edge region 112 is a rectangle ring-shaped region occupying a length ratio of 15% to 25% from the side surface of the semiconductor chip. The center region 111 is a region other than the edge region 112 having the rectangle ring-shaped region. A rectangle ring-shaped refers to a structure that has the general shape of a ring but with a rectangular cross-section. Bump structures 130 may be appropriately disposed in the center region 111 and the edge region 112, depending on the shape of warpage of the semiconductor chip.

In an exemplary embodiment, the edge region 112 may include corner portions 112C and line portions 112L. The line portions 112L may at least partially surround the four sides of the center region 111. For example, the line portions 112L may extend in the first direction D1, the opposite to the first direction −D1, the third direction D3, and the opposite to the third direction −D3 from the center region 111. The corner portions 112C may refer to regions of the edge region 112 excluding the line portions 112L. For example, the corner portion 112C is in contact with the corner of the center region 111.

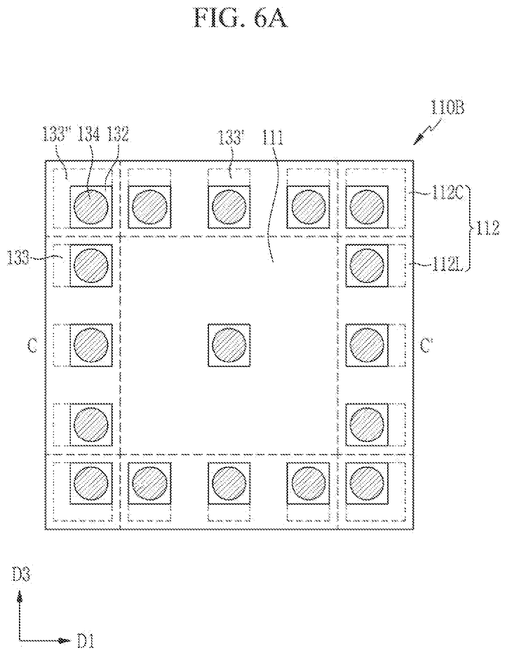

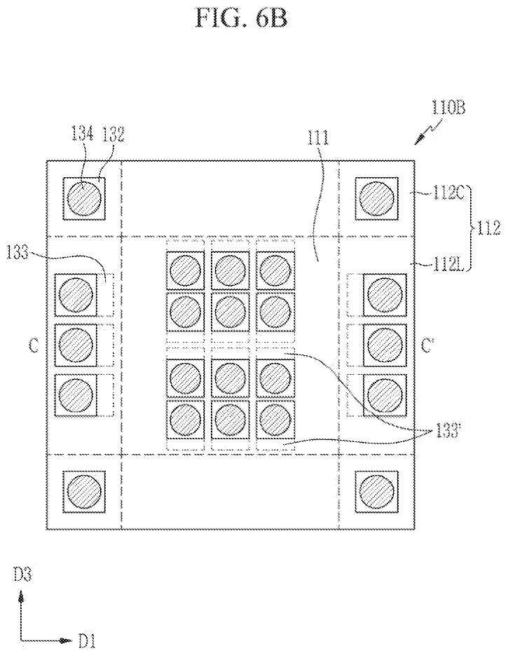

FIG. 6A and FIG. 6B are arrangements of bump structures 130 on the rear surfaces 110B of semiconductor chips.

Referring to FIG. 6A, in an exemplary embodiment, a density of the bump structures 130 on the edge region 112 of the rear surface 110B of a semiconductor chip may be higher than the density of the bump structures 130 on the center region 111. For example, the bump structures 130 including second bump pads 132 with extension portions 133, 133′, or 133″ may be disposed more in the edge region 112 of the rear surface 110B of the semiconductor chip than in the center region 111. Since the bump structures 130 including the second bump pads 132 with the extension portions 133, 133′, or 133″ may be disposed more in the edge region 112 of the rear surface 110B of the semiconductor chip than in the center region 111, a metal wetting force may flatten the edge region 112 of another semiconductor chip stacked on the rear surface 110B of the semiconductor chip.

For example, fewer bump structures 130 in the center region 111 of the rear surface 110B of the semiconductor chip than in the edge region 112 may prevent the formation of a downwardly convex shape, such as smile warpage, in the center region 111 of another semiconductor chip stacked on the rear surface 110B of the semiconductor chip.

In an exemplary embodiment, the density of bump pads 132 including the extension portions 133, 133′, or 133″ may satisfy the following Expression 1.

$$MP \times 1.5 < EG \qquad < Expression 1 >$$

(In the above Expression 1, MP refers to the density of the bump pads 131 and 132 that are disposed on the center region 111, and EG refers to the density of the bump pads 131 and 132 that are disposed on the edge region 112.)

For example, the above Expression 1 is an indicator of the density of the bump pads 131 and 132 including the extension portions 133, 133′, or 133″, and defines the density distribution in which the bump pads 131 and 132 are disposed on the rear surface 110B of the semiconductor chip to prevent cry warpage of the semiconductor chips. For example, Expression 1 is an inductive relationship between the center region 111 and the edge region 112 of the rear surface 110B of the semiconductor chip. When the density of the bump pads 131 and 132 including the extension portions 133, 133′, or 133″ satisfies the above-mentioned Expression 1, it is possible to prevent smile warpage in which the center region 111 is warped in a downwardly convex shape.

Referring to FIG. 6B, in an exemplary embodiment, the density of the bump structures 130 on the center region 111 of the rear surface 110B of a semiconductor chip may be higher than the density of the bump structures 130 on the edge region 112. For example, the bump structures 130 including the second bump pads 132 with the extension portions 133, 133′, or 133″ may be disposed more in the center region 111 of the rear surface 110B of the semiconductor chip than in the edge region 112. Since the bump structures 130 including the second bump pads 132 with the extension portions 133, 133′, or 133″ may be disposed more in the center region 111 of the rear surface 110B of the semiconductor chip than in the edge region 112, a metal wetting force may flatten the edge region 112 of another semiconductor chip stacked on the rear surface 110B of the semiconductor chip. For example, fewer bump structures 130 in the edge region 112 of the rear surface 110B of the semiconductor chip than in the center region 111 may prevent the formation of a upwardly convex shape, such as cry warpage, in the center region 111 of the semiconductor chips.

In an exemplary embodiment, the density of the bump pads 131 and 132 including the extension portions 133, 133′, or 133″ may satisfy the following Expression 2.

$$EG \times 1.5 < MP \qquad < Expression 2 >$$

(In the above Expression 2, EG refers to the density of bump pads 131 and 132 that are disposed on the edge region 112, and MP refers to the density of bump pads 131 and 132 that are disposed on the center region 111.)

For example, the above Expression 2 is an indicator of the density of bump pads 131 and 132 including the extension portions 133, 133′, or 133″, and defines the density distribution in which the bump pads 131 and 132 are disposed on the rear surface 110B of the semiconductor chip to prevent cry warpage of semiconductor chips. For example, Expression 2 is an inductive relationship between the center region 111 and the edge region 112 of the rear surface 110B of the semiconductor chip. When the density of the bump pads 131 and 132 and 132 including the extension portions 133, 133′, or 133″ satisfies the above-mentioned Expression 2, it is possible to prevent cry warpage in which the center region 111 is warped in an upward convex shape.

In an exemplary embodiment, the ratio of the planar area of the bump pads 131 and 132 with the extension portions 130 to the planar area of the first semiconductor chip 110 or the second semiconductor chip 120 may be within a range of 2.05% to 3.50%. For example, the ratio which is the percentage of the planar area of bump pads 131 and 132 with extension portions 133, 133′, or 133″, for example, second bump pads 132, abutting the first semiconductor chip 110 in the planar area of the substrate of the first semiconductor chip 110 may satisfy the above-mentioned range.

The above-mentioned ratio may be within a range of 2.05% to 3.50%, for example, a range from 2.55% to 3.19%. When the ratio surpasses the specified upper limit of 3.50%, the ratio of the bump structures 130 including the extension portions 133, 133′, or 133″ may become economically insufficient. Additionally, the high ratio of the bump structures 130 may pose a risk of interference between the bump structures 130, potentially leading to a short circuit. When the ratio is smaller than the specified lower limit of 2.05%, the ratio of bump structures 130 including the extension portions 133, 133′, or 133″ may be so low that there is a problem that the effect expressed from the bump structures 130 including the extension portions 133 is insufficient.

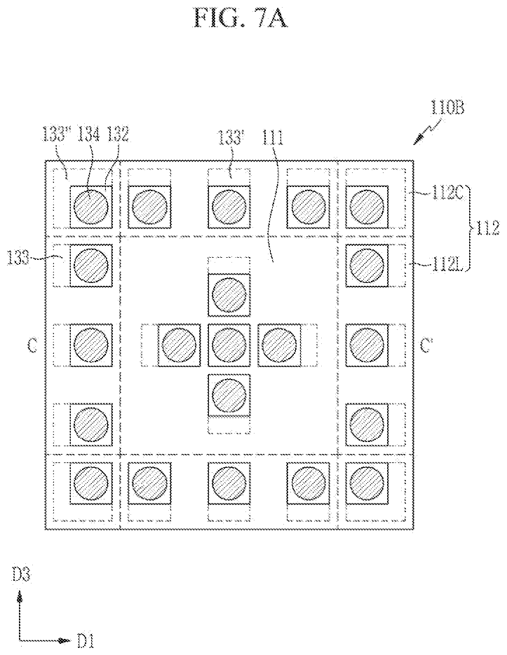

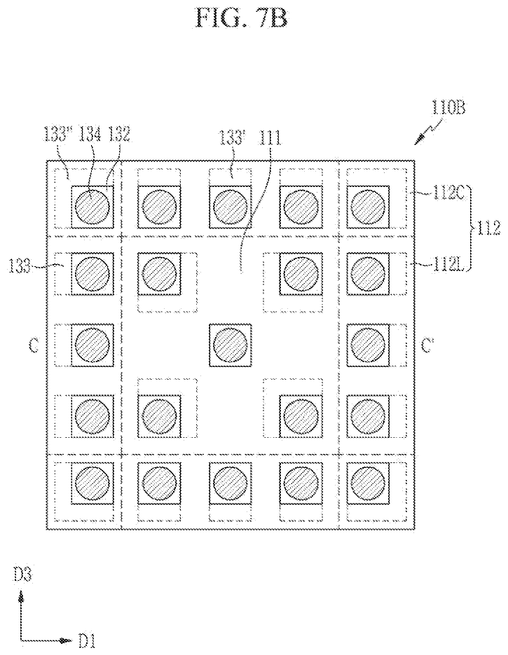

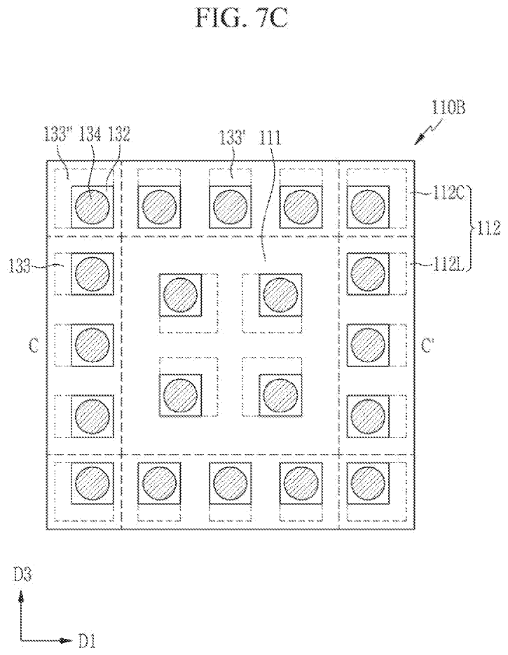

FIG. 7A to FIG. 7C are various arrangements of bump structures according to an exemplary embodiment of the present disclosure.

Referring to FIG. 7A to 7C, the bump structures 130 are disposed more on the edge region 112 of the rear surface 110B of a semiconductor chip than on the center region 111. This arrangement may prevent smile warpage of semiconductor chips. The second bump pads 132 with extension portions 133, 133′, or 133″ may be disposed more on the edge region 112 of the rear surface 110B of a semiconductor chip than on the center region 111, thereby preventing smile warpage and flattening semiconductor chips.

The exemplary embodiment, however, is not necessarily limited thereto. For example, the arrangement of the extension portions 133, 133′, or 133″ on the edge region 112 may be modified, and may include various exemplary embodiments as long as the second bump pads 132 with the extension portions 133, 133′, or 133″ are disposed more on the edge region 112 of the rear surface 110B of a semiconductor chip than on the center region 111.

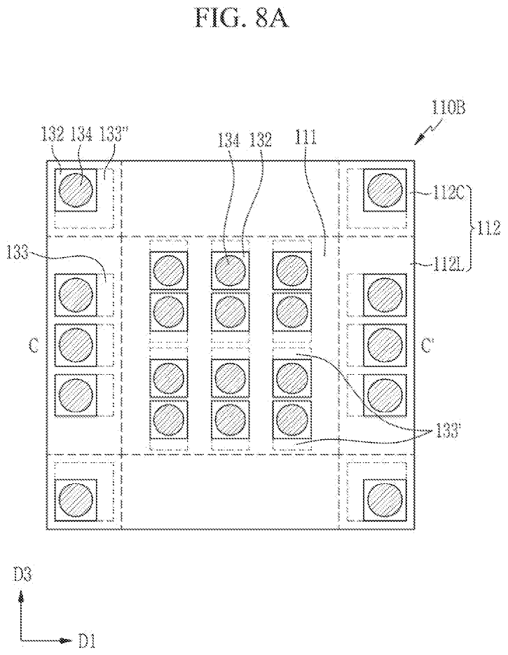

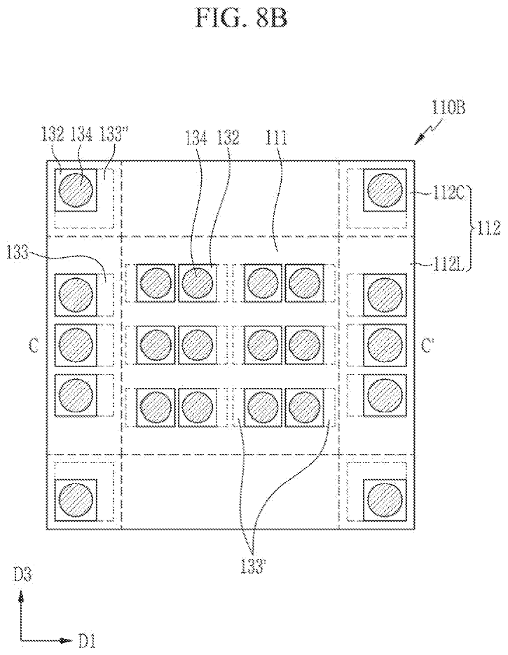

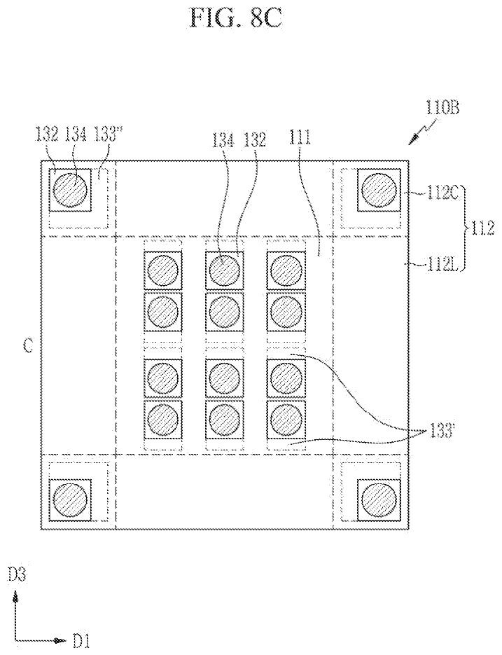

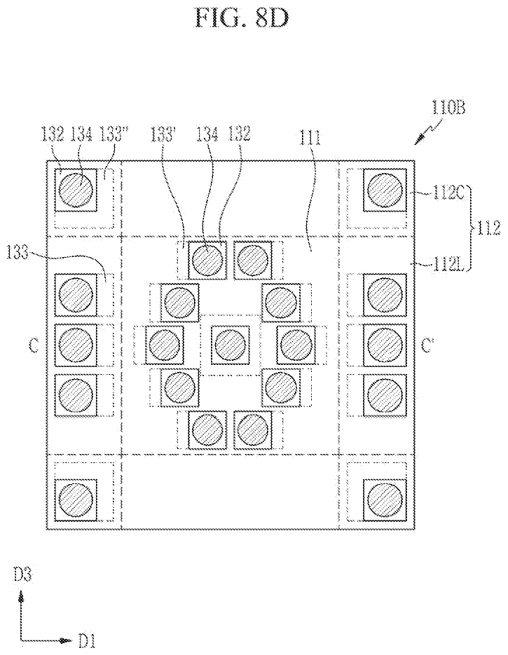

FIG. 8A to FIG. 8D are various arrangements of bump structures according to an exemplary embodiment of the present disclosure.

Referring to FIG. 8A to FIG. 8D, the bump structures 130 are disposed more on the center region 111 of the rear surface 110B of a semiconductor chip than on the edge region 112. This arrangement may prevent cry warpage of semiconductor chips. The second bump pads 132 with the extension portions 133, 133′, or 133″ may be disposed more on the center region 111 of the rear surface 110B of a semiconductor chip than on the edge region 112, thereby preventing cry warpage and flattening semiconductor chips.

The exemplary embodiment, however, is not necessarily limited thereto. For example, the arrangement of the extension portions 133, 133′, or 133″ on the edge region 112 may be modified as described above, and may include various exemplary embodiments as long as the second bump pads 132 with the extension portions 133, 133′, or 133″ are disposed more on the center region 111 of the rear surface 110B of a semiconductor chip than on the edge region 112.

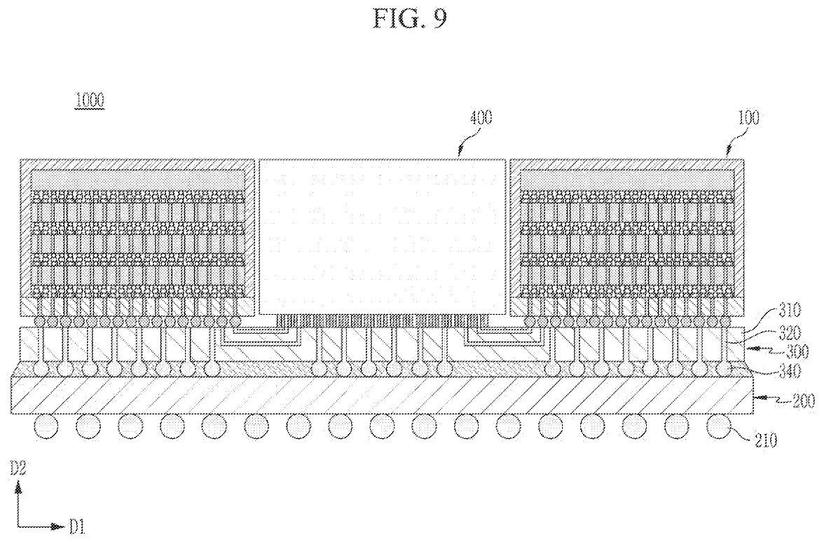

FIG. 9 is a semiconductor package 1000 according to an exemplary embodiment of the present disclosure.

Referring to FIG. 9, the semiconductor package 1000 according to the exemplary embodiment may include a semiconductor stack structure 100, a package substrate 200, an interposer 300, a processor chip 400, and an external sealing material.

The semiconductor stack structure 100 is disposed on the interposer 300. The semiconductor stack structure 100 includes a plurality of semiconductor chips stacked, and at least one bump structure 130 which is disposed between the plurality of semiconductor chips. The bump structure 130 electrically connects the plurality of semiconductor chips. The bump structures 130 may include first bump pads 131 and second bump pads 132 having pad areas different from each other.

For example, the bump structures 130 may be disposed in the joint gaps between the plurality of semiconductor chips in the semiconductor stack structure 100. The joint gaps refer to regions in which the bump structures 130 are disposed between the semiconductor chips for electrical coupling or physical supporting. The bump structures 130 may draw upon the description provided under FIG. 1A to FIG. 8D.

On the outer surface of the package substrate 200, external connection terminals 210 such as solder bumps may be disposed. For example, the external connection terminals 210 may be disposed on the base surface of the package substrate 200. The semiconductor package 1000 may be mounted on another external board so as to be electrically coupled to other devices through the external connection terminals 210.

The interposer 300 may be disposed on the package substrate 200 and may convert or transfer electrical input signals between the semiconductor stack structure 100, the processor chip 400, and the package substrate 200. The interposer 300 may include an interposer substrate 310, interposer TSVs 320, interposer pads, an interposer wiring layer, and interposer bumps 340.

The interposer substrate 310 may be formed from any one of silicon, organic material, plastic, and glass substrates. For example, when the interposer substrate 310 of the interposer 300 is a silicon substrate, the interposer 300 may be used as a silicon interposer. When the interposer substrate 310 is an organic substrate, the interposer 300 may be used as a panel interposer. As for the silicon interposer and the panel interposer, the number of panel interposers manufactured on a rectangular original organic panel may be greater than the number of silicon interposers manufactured on a single silicon wafer.

The interposer TSVs 320 may vertically extend from the upper surface of the interposer substrate 310 to the lower surface of the interposer substrate 310 while passing through the interposer substrate 310. The interposer TSVs 320 may extend into a wiring layer 340. When the interposer substrate 310 is silicon, the interposer TSVs 320 may be referred to as TSVs. Regarding other structures and materials of the through-silicon vias 320, the description of the first TSVs 110V of the semiconductor package 100 in FIG. 1A may be referred to. In some embodiments, the interposer 300 may only include the wiring layer 340, and not any interposer TSVs 320.

The interposer pads may be disposed on the upper surface of the substrate 310, and be disposed so as to be electrically connected to the interposer TSVs 320. On the interposer pads, the semiconductor stack structure 100 and the processor chip 400 may be stacked, such that the semiconductor stack structure 100 and the processor chip 400 are electrically connected to the package substrate 200. FIG. 9 illustrate the interposer pads embedded within the interposer 300, and the vertical bonding of the interposer pads with bumps 180 of the semiconductor package 1000.

The interposer wiring layer may have a single-layer or multi-layer wiring structure. The interposer TSVs 320 may vertically pass through at least some portions of the interposer wiring layer 340 so as to be electrically connected to the wiring lines of the interposer wiring layer. When two or more interposer wiring layers are provided, the wiring lines in the different layers may be connected through vertical contacts. The interposer wiring layer may be disposed either on the lower surfaces of the interposer TSVs 320 or on the upper parts of the interposer TSVs 320, resulting in a relative positional relation between the interposer wiring layer and the interposer TSVs 320.

The interposer bumps 340 may be disposed below the interposer 300 and electrically connected to wiring lines of the interposer wiring layer. The interposer bumps 340 may be used to stack and/or mount the interposer 300 on the package substrate 200, such as a printed circuit board (PCB). The interposer bumps 340 may be coupled to the interposer pads through the wiring lines of the interposer wiring layer and the interposer TSVs 320. Among the interposer pads, interposer pads which are used for a power, or a ground may be integrated and are coupled to the interposer bumps 340 together. Accordingly, the number of interposer pads may be greater than the number of the interposer bumps 340.

The processor chip 400 may be mounted on the interposer and may be disposed adjacent to the semiconductor stack structure 100. For example, the processor chip 400 may be disposed between the two semiconductor stack structures 100. The processor chip 400 may be a GPU/CPU/SOC chip. Depending on the types of elements included in the processor chip 400, the semiconductor package 1000 may be categorized as either a semiconductor package 1000 for servers or a semiconductor device for mobile devices.

The external sealing material may include a material such as an epoxy molding compound. In an exemplary embodiment, the external sealing material may be formed together with the sealing material of the semiconductor stack structure 100. In an exemplary embodiment, the external sealing material may cover only the upper surface of the processor chip 400 of the semiconductor stack structure 100 and might not cover the upper surface of the semiconductor stack structure 100. Like in FIG. 9, the semiconductor stack structure 100 may be applied not only to 2.5D semiconductor packages but also to any other structures in which semiconductor chips are stacked in a stack form, such as 2.1D semiconductor packages or 3D semiconductor packages.

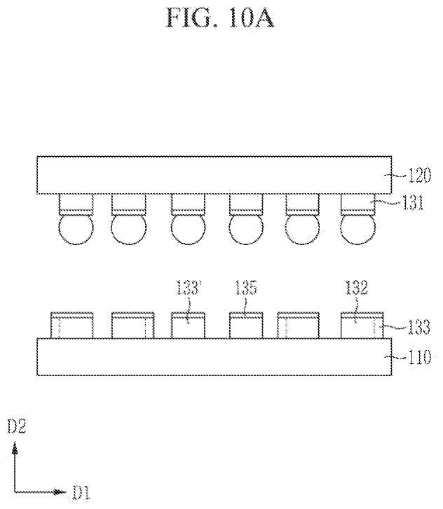

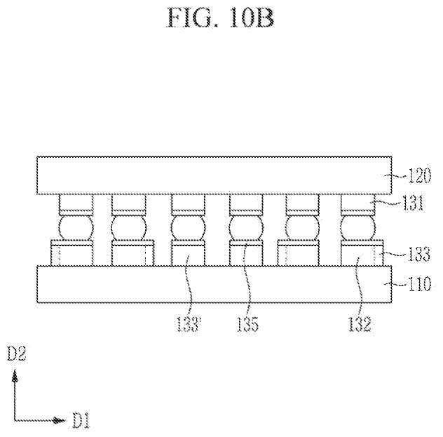

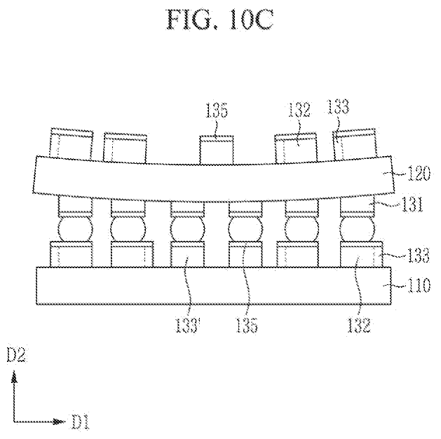

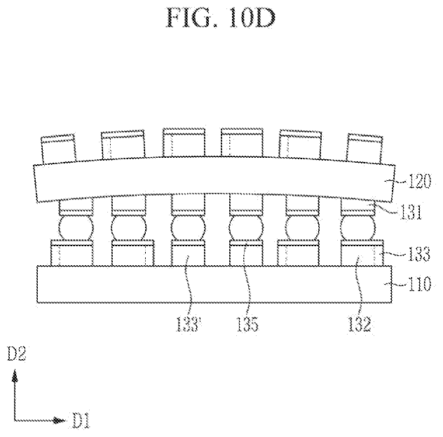

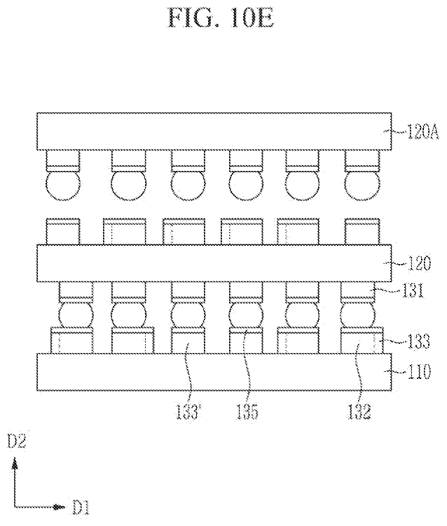

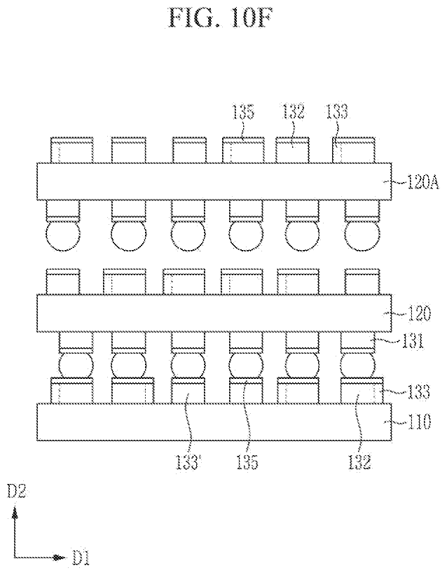

FIG. 10A to FIG. 10F are illustrating a method of manufacturing a semiconductor package according to an exemplary embodiment of the present disclosure.

Referring to FIG. 10A, in an exemplary embodiment, a method of manufacturing a semiconductor package includes a step of preparing a first semiconductor chip 110, a step of depositing second bump pads 132 on the first semiconductor chip 110, and a step of preparing a second semiconductor chip 120 with first bump pads 131 deposited thereon. Regarding the first semiconductor chip 110, the second semiconductor chip 120, the first bump pads 131, and the second bump pads 132, the above description may be referred to.

In an exemplary embodiment, at least one of the step of depositing the second bump pads 132 on the first semiconductor chip 110 and the step of preparing the second semiconductor chip 120 with the first bump pads 131 deposited thereon may include a step of disposing extension portions 133 on at least one side of each of either the first bump pads 131 or the second bump pads 132. For example, the extension portions 133 may be disposed on at least one side of either the first bump pads 131 or the second bump pads 132, depending on a warpage shape of the semiconductor chips.

In an exemplary embodiment, the step of disposing the extension portions 133 on at least one side of each of either the first bump pads 131 or the second bump pads 132 may dispose the extension portions simultaneously with the deposition of the first bump pads 131 or the second bump pads 132. For example, when the first bump pads 131 or the second bump pads 132 are deposited, the extension portions 133 may be deposited so as to be disposed on one side of each of either the first bump pads 131 or the second bump pads 132, by adjusting the disposition of a mask.

In an exemplary embodiment, the step of disposing the extension portions 133 on at least one side of each of either the first bump pads 131 or the second bump pads 132 may involve deposition of the first bump pads 131 or the second bump pads 132, followed by a separate step for disposing the extension portions 133. Since the extension portions 133 are added subsequent to depositing the first bump pads 131 or the second bump pads 132, it is possible to manage the material composition of the extension portions 133 independently of the material used for the first bump pads 131 or the second bump pads 132, allowing the usage of different materials. FIG. 10A shows the case where the extension portions 133 are disposed only on the second bump pads 132; however, the exemplary embodiment is not necessarily limited thereto. For example, all cases, whether the extension portions 133 are placed only on the first bump pads 131 or simultaneously on both the first bump pads 131 and the second bump pads 132, may be considered, provided there is a distinction in the area ration between the first bump pads 131 and the second bump pads 132.

In an exemplary embodiment, the step of depositing the second bump pads 132 on the first semiconductor chip 110 and the step of preparing the second semiconductor chip 120 with the first bump pads 131 deposited thereon may include a step of controlling the arrangement of the first bump pads 131 or the second bump pads 132 in view of the shape of warpage of semiconductor chips.

For example, by predicting warpage of semiconductor chips when the semiconductor chips form a stacked structure, the extension portions 133 may be disposed on the first bump pads 131 or the second bump pads 132, and the first bump pads 131 or the second bump pads 132 with the extension portions 133 may be disposed in various forms. For example, by predicting that semiconductor chips will exhibit smile warpage, bump structures 130 including the extension portions 133 may be disposed more densely on the edge region 112 of the rear surface 110B of a semiconductor chip than on the center region 111, as shown in FIG. 7A to FIG. 7C.

In an exemplary embodiment, by predicting that semiconductor chips will exhibit cry warpage, the bump structures 130 including the extension portions 133 may be disposed more densely on the center region 111 of the rear surface 110B of a semiconductor chip than on the edge region 112, as shown in FIG. 8A to FIG. 8D.

In an exemplary embodiment, a step of further depositing a bonding layer 135 on the second bump pads 132 is included. By forming the bonding layer 135, it is possible to further improve the adhesion of the first bump pads 131 and the second bump pads 132 that are bonded by solder bumps 134.

Referring to FIG. 10B, the method of manufacturing a semiconductor package may include a step of stacking the second semiconductor chip 120 on the first semiconductor chip 110. In an exemplary embodiment, the step of stacking the second semiconductor chip 120 on the first semiconductor chip 110 may be performed in a thermal compression bonding (TCB) process of bonding the semiconductor chips at high temperature by providing heat and pressure of a bonding head. In an exemplary embodiment, the step of stacking the second semiconductor chip 120 on the first semiconductor chip 110 may include a step of bonding the first semiconductor chip 110 to the second semiconductor chip 120, and might not be performed at high temperature. For example, stacking of a plurality of semiconductor chips may include cases where the semiconductor chips are stacked in a high-temperature environment and cases where semiconductor chips are stacked at room temperature or below.

Referring to FIG. 10C, the method of manufacturing a semiconductor package may include a step of depositing second bump pads 132 including the extension portions 133 on the second semiconductor chip 120. For example, for flattening of a semiconductor chip to be additionally disposed on the second semiconductor chip 120 after stacking the second semiconductor chip 120 on the first semiconductor chip 110, second bump pads 132 may be disposed on the second semiconductor chip 120 so as to have any one of the arrangements in FIG. 7A to 7C or FIG. 8A to FIG. 8D.

In an exemplary embodiment, a step of determining the shape of warpage of the second semiconductor chip 120 stacked on the first semiconductor chip 110 may be included, and according to the warpage shape, second bump pads 132 including the extension portions 133 may be deposited on the second semiconductor chip 120. For example, the semiconductor package may have a smile warpage shape like in FIG. 10C. When at least one semiconductor chip of the semiconductor package has a smile warpage shape, bump pads 131 and 132 may be disposed more densely on the edge region 112 of the rear surface 110B of the semiconductor chip than on the center region 111 like in FIGS. 7A to 7C described above.

Referring to FIG. 10D, at least one semiconductor chip of the semiconductor package may have a cry warpage shape. When at least one semiconductor chip of the semiconductor package has a cry warpage shape which is an upwardly convex shape, bump pads 131 and 132 may be disposed more densely on the center region 111 of the rear surface 110B of the semiconductor chip than on the edge region 112 like in FIGS. 8A to 8D described above.

Referring to FIG. 10E, a step of stacking a third semiconductor chip 120A with the first bump pads 131 deposited thereon on the second semiconductor chip 120 may be included. The third semiconductor chip 120A may be stacked on the second semiconductor chip 120 such that the deposited first bump pads 131 are disposed on the second bump pads 132 disposed on the second semiconductor chip 120, considering the disposition relationship between the second bump pads 132.

Referring to FIG. 10F, a step of disposing the second bump pads 132 on the third semiconductor chip 120A may be included. As described above, the step of disposing the second bump pads 132 on the third semiconductor chip 120A may dispose the second bump pads 132 by predicting the shape of warpage of an additional semiconductor chip to be stacked on the third semiconductor chip. In an exemplary embodiment, when the third semiconductor chip 120A has a smile warpage or cry warpage shape, the step of disposing the second bump pads 132 on the third semiconductor chip 120A may dispose the second bump pads 132, considering the warpage shape.

As described above, bump structures 130 including the extension portions 133 may be disposed in various forms depending on the shape of warpage of the semiconductor chips constituting the semiconductor stack structure 100, such that warpage of the semiconductor chips is restrained, whereby the semiconductor package 1000 of the present disclosure can be flattened.

The present disclosure is not limited to the above implementation examples and/or embodiments, and may be manufactured in various other forms, and those skilled in the art will understand that the present disclosure may be carried out in other specific forms without altering the technical spirit and essential features of the present disclosure. It should therefore be appreciated that the implementation examples and/or embodiments described above are exemplary in all respects and are not intended to be limiting.

What is claimed is:

1. A semiconductor package, comprising:
a first semiconductor chip;
a second semiconductor chip disposed on the first semiconductor chip; and
at least one bump structure disposed between the first semiconductor chip and the second semiconductor chip, wherein the bump structure includes a first bump pad and a second bump pad with different planar areas.

2. The semiconductor package of claim 1, wherein
the planar area of the bump structure is in contact with either the first semiconductor chip or the second semiconductor chip.

3. The semiconductor package of claim 1, wherein
either the first bump pad or the second bump pad includes an extension portion that extends horizontally in at least one direction,
wherein the direction includes a first direction, a direction opposite to the first direction, a second direction intersecting the first direction in a horizontal direction; and a direction opposite to the second direction;
wherein the extension portion extends from the first bump pad or the second bump pad.

4. The semiconductor package of claim 2, wherein
the first bump pad or the second bump pad including an extension portion has a larger planar area.

5. The semiconductor package of claim 2, wherein
a width-to-height ratio of either the first bump pad or the second bump pad including the extension portion is equal to or greater than 7.5.

6. The semiconductor package of claim 2, wherein
a length of the extension portion disposed parallel to the front surface of either the first semiconductor chip or the second semiconductor chip is within a range greater than 0 and less than or equal to 0.8 μm.

7. The semiconductor package of claim 2, wherein
a ratio of the surface area of the bump pads, including the extension portions, to the surface area of either the first or second semiconductor chip is within a range of 2.05% to 3.50%.

8. The semiconductor package of claim 2, wherein
rear surfaces of the first semiconductor chip and the second semiconductor chip include center regions and edge regions,
wherein the edge regions surround the center regions and occupy a length ratio of 15% to 25% from side surfaces of the first semiconductor chip and the second semiconductor chip.

9. The semiconductor package of claim 1, wherein
densities of the bump structures on the edge regions are higher than densities on the center regions.

10. The semiconductor package of claim 9, wherein
densities of the bump pads including the extension portions satisfies the following Expression 1:
$$MP \times 1.5 < EG \qquad < Expression 1 >$$
wherein MP refers to the density of bump pads that are disposed on the center region and EG refers to the density of bump pads that are disposed on the edge region.

11. A semiconductor package, comprising:
a first semiconductor chip;
a second semiconductor chip disposed on the first semiconductor chip; and
at least one bump structure that is disposed between the first semiconductor chip and the second semiconductor chip, electronically connecting the two,
wherein the bump structure includes a first bump pad and a second bump pad, and their planar areas differ,
wherein rear surfaces of the first semiconductor chip and the second semiconductor chip include center regions and edge regions that surrounds the center regions, and
wherein densities of the bump structures on the center regions and densities of the edge regions are different from each other.

12. The semiconductor package of claim 11, wherein
the planar area of the bump structure is in contact with either the first semiconductor chip or the second semiconductor chip.

13. The semiconductor package of claim 12, wherein
densities of bump pads including the extension portions satisfies the following Expression 1 or Expression 2:
$$MP \times 1.5 < EG \qquad < Expression 1 >$$
$$EG \times 1.5 < MP \qquad < Expression 2 >$$
wherein MP refers to the density of bump pads that are disposed on the center region and EG refers to the density of bump pads that are disposed on the edge region.

14. The semiconductor package of claim 13, wherein either the first bump pad or second bump pad includes an extension portion that extends in at least one direction,
wherein the direction includes a first direction, a direction opposite to the first direction, a second direction intersecting the first direction in a horizontal direction, and a direction opposite to the second direction.

15. The semiconductor package of claim 14, wherein
a width-to-height ratio of the bump pad including the extension portion is equal to or greater than 7.5.

16. The semiconductor package of claim 14, wherein
a ratio of the surface area of the bump pads, including the extension portions, to the surface area of either the first or second semiconductor chip is within a range of 2.05% to 3.50%.

17. A semiconductor package, comprising:
a package substrate;
an interposer that is disposed on the package substrate; and
a semiconductor stack structure that is disposed on the interposer and in which a plurality of semiconductor chips is stacked,
wherein the semiconductor stack structure includes at least one bump structure that is disposed between the plurality of semiconductor chips,
wherein the bump structure includes a first bump pad and a second bump pad with different planar areas, and the planar area of the bump structure is in contact with either the first semiconductor chip or the second semiconductor chip,
wherein either the first bump pad or the second bump pad includes an extension portion that extends horizontally in at least one direction, and
wherein the direction includes a first direction, a direction opposite to the first direction, a second direction intersecting the first direction in a horizontal direction; and a direction opposite to the second direction.

18. The semiconductor package of claim 17, wherein
at least one the bump structure is disposed in joint gaps among the plurality of semiconductor chips, and
densities of the at least one bump structure that is disposed in the plurality of joint gaps vary.

19. The semiconductor package of claim 17, wherein
the densities of the at least one bump structure that is disposed in the plurality of joint gaps satisfy the following Expression 1 or Expression 2:
$$MP \times 1.5 < EG \qquad < Expression 1 >$$
$$EG \times 1.5 < MP \qquad < Expression 2 >$$
wherein MP refers to the density of bump pads that are disposed on the center region and EG refers to the density of bump pads that are disposed on the edge region.

20. The semiconductor package of claim 17, wherein
a ratio of the surface area of the bump pads, including the extension portions, to the surface area of either the first or second semiconductor chip is within a range of 2.05% to 3.50%.
